(19) United States
(12) Patent Application Publication
(10) Pub. No.: US 2025/0239738 A1
(43) Pub. Date: Jul. 24, 2025

(54) BATTERY MODULE AND BATTERY MODULE COLLECTION MECHANISM

(71) Applicant: EVE ENERGY CO., LTD., Huizhou (CN)

(72) Inventor: Caiyu LI, Huizhou (CN)

(73) Assignee: EVE ENERGY CO., LTD., Huizhou (CN)

(21) Appl. No.: 18/986,382

(22) Filed: Dec. 18, 2024

(30) Foreign Application Priority Data
Dec. 18, 2023 (CN) 202323464404.X
Apr. 30, 2024 (WO) PCT/CN2024/091043

(51) Int. Cl. H01M 50/503; H01M 50/209; H01M 50/505; H01M 50/51

(52) U.S. Cl. CPC H01M 50/503; H01M 50/209; H01M 50/505; H01M 50/51

(57) ABSTRACT

A battery module and a battery module collection mechanism are provided. The battery module collection mechanism includes: a bracket, and a collection group including a serial assembly, where the serial assembly includes a first serial group, a second serial group, and a first connection member all disposed on the bracket, the first serial group and the second serial group each includes a first serial row and a second serial row arranged oppositely, and the first serial group and the second serial group each is connected in series with a cell group, and two first serial rows or two second serial rows of the first serial group and the second serial group are connected to each other by the first connection member.

### CROSS REFERENCE TO RELATED APPLICATION

This application claims priority to Chinese Patent Application No. 202323464404.X, filed with the Chinese Patent Office on Dec. 18, 2023, and further claims priority to an International Application No. PCT/CN2024/091043, filed on Apr. 30, 2024, content of both of which are incorporated herein by reference in their entireties.

### TECHNICAL FIELD

The present disclosure relates to the field of battery technologies, and more particular to a battery module and a battery module collection mechanism.

### BACKGROUND

In the related art, a plurality of battery modules of a battery system may be connected in series with each other by an aluminum bar, and Cells Contact System (CCS) assemblies of the plurality of battery modules may be connected to a Battery Management System (BMS) through a plurality of transfer harnesses. As such, the harnesses of the integrated battery modules may be complicated, and Cell Supervision Circuits (CSC) assemblies of the plurality of battery modules may occupy installation positions between the battery modules, thereby reducing energy density.

### SUMMARY

The present disclosure provides a battery module and a battery module collection mechanism, which can improve the low energy density.

In a first aspect, embodiments of the present disclosure provide a battery module collection mechanism, including: a bracket; and a collection group including a serial assembly; where the serial assembly includes a first serial group, a second serial group, and a first connection member all installed in the bracket, the first serial group and the second serial group each include a first serial row and a second serial row arranged oppositely, and the first serial group and the second serial group each is connected in series with a cell group, two first serial rows or two second serial rows of the first serial group and the second serial group are connected to each other by the first connection member.

In a second aspect, embodiments of the present disclosure provide a battery module, including: two collection groups, one or more battery grouping assemblies, and the above-described battery module collection mechanism provided in a number corresponding to a number of the battery grouping assemblies, where each of the battery grouping assemblies includes four cell groups, and each of the collection groups corresponds to two of the cell groups.

### Beneficial Effects

The beneficial effects of the present disclosure are as follows: the present disclosure provides a battery module collection mechanism which integrates the cell group corresponding to the first serial group with the cell group corresponding to the second serial group by providing the first serial group and the second serial group on the same bracket and connecting the cell group corresponding of the first serial group to the cell group corresponding of the second serial group with the first connection member, thereby facilitating the two cell groups to share a cell signal collection device, further reducing the CSC assembly connected to the cell signal collection device, saving a portion of space originally used for installing the CSC assembly so as to install more cells, and improving the energy density to solve the low energy density in the related art.

The present disclosure provides a battery module, including: two collection groups, one or more battery grouping assemblies, and the above-described battery module collection mechanism provided in a number corresponding to a number of the battery grouping assemblies. The battery module collection mechanism enables the cell groups to share a cell signal collection device, reduces the CSC assembly connected to the cell signal collection device to install more cells, and improves the energy density to solve the low energy density in the related art.

### DESCRIPTION OF THE DRAWINGS

FIG. 1 is a schematic structural diagram of a battery module according to some embodiments of the present disclosure.

FIG. 2 is an enlarged view of a portion A in FIG. 1.

FIG. 3 is a perspective diagram of a collection assembly according to some embodiments of the present disclosure.

FIG. 4 is an enlarged view of a portion B in FIG. 3.

FIG. 5 is a perspective diagram of a first connection member according to some embodiments of the present disclosure.

FIG. 6 is a perspective diagram of a bracket according to some embodiments of the present disclosure.

FIG. 7 is a schematic structural diagram of one side of two battery module collection mechanisms toward cells according to some embodiments of the present disclosure.

FIG. 8 is an enlarged view of a portion C in FIG. 7.

FIG. 9 is a schematic structural diagram of a first positioning member according to some embodiments of the present disclosure.

FIG. 10 is a schematic structural diagram of a battery module collection mechanism according to some embodiments of the present disclosure.

FIG. 11 is a schematic structural diagram of a battery module according to some embodiments of the present disclosure.

### REFERENCE NUMERALS OF THE ACCOMPANYING DRAWING

1. Battery module collection mechanism; 100. Collection group; 110. Serial assembly; 120. Collection assembly; 11. First serial group; 12. Second serial group; 101. First serial row; 102. Second serial row; 13. First collection line; 131. First connection portion; 132. First buffer portion; 133. First groove; 14. Second collection line; 141. Second connection portion; 142. Second buffer portion; 143. Second groove; 21. First connection member; 211. First protrusion; 212. First recess; 22. First integrated member; 23. Second integrated member; 3. Bracket; 31. Collection line installing groove; 32. Connection member installing groove; 33. Explosion-proof hole; 4. Connection circuit board; 5. First positioning member; 51. First positioning groove; 6. Second positioning member; 61. Second positioning groove; 7. Cell grouping assembly; 71. Cell group.

### DETAILED DESCRIPTION

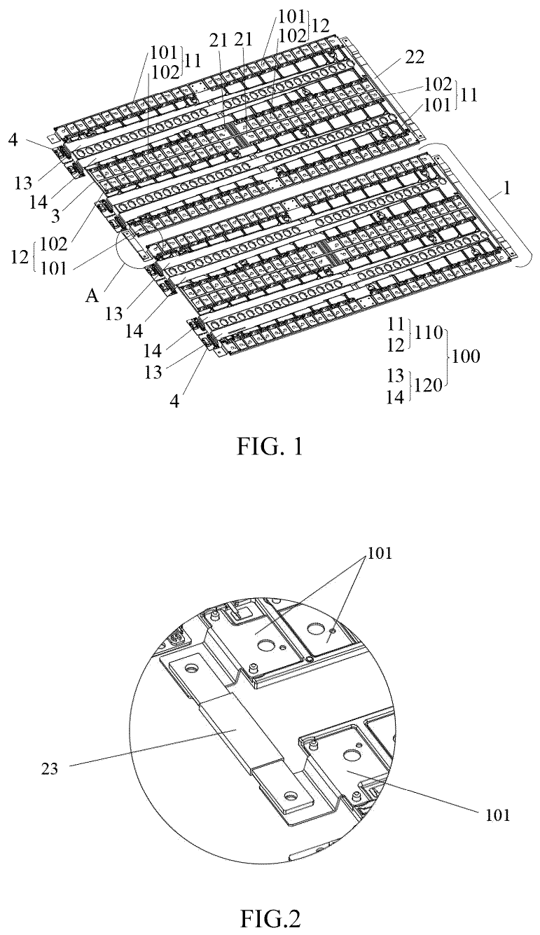

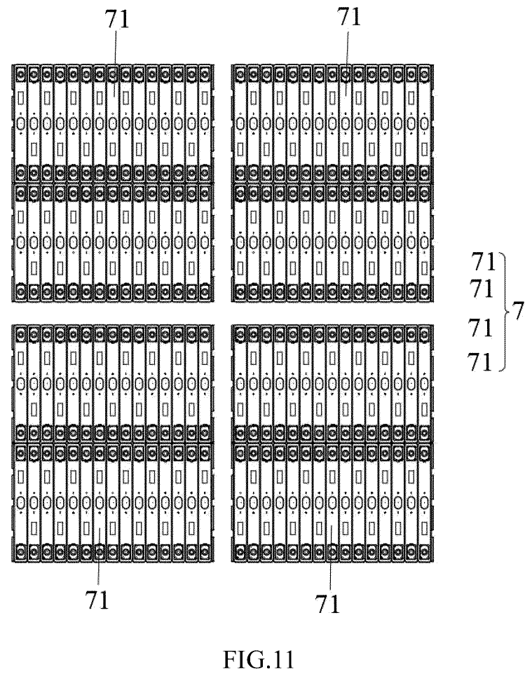

Referring to FIGS. 1 and 11, a battery module collection mechanism 1 provided in the embodiments of the present disclosure may include: a bracket 3; and a collection group 100 including a serial assembly 110; where the serial assembly 110 includes a first serial group 11, a second serial group 12, and a first connection member 21 all installed on the bracket 3, the first serial group 11 and the second serial group 12 each includes a first serial row 101 and a second serial row 102 arranged oppositely, and the first serial group 11 and the second serial group 12 each is connected in series with a cell group 71, two first serial rows 101 or two second serial rows 102 of the first serial group 11 and the second serial group 12 are connected to each other by the first connection member 21.

The first serial row 101 and the second serial row 102 may be provided on the same bracket 3, so that the cell groups 71 corresponding to the first serial row 101 and the second serial row 102 can be installed more closely, thereby improving the space utilization rate. Additionally, integration of the cell group 71 corresponding to the first serial row 101 with the cell group 71 corresponding to the second serial row 102 may be realized by connecting the first serial row 101 with the second serial row 102 through the first connection member 21, so that the two cell groups 71 can share a cell signal collection device, thereby reducing the CSC assembly connected to the cell signal collection device, saving a portion of the space originally used for installing the CSC assembly so as to install more cells, and improving the energy density.

Referring to FIGS. 1 and 11, a battery module collection mechanism 1 provided in the embodiments of the present disclosure may include: a bracket 3; and a collection group 100. The collection group 100 may include a serial assembly 110 and a collection assembly 120.

The serial assembly 110 may include a first serial group 11, a second serial group 12, and a first connection member 21 all installed on the bracket 3.

The collection assembly 120 may include a first collection line 13 and a second acquisition line 14 that both are installed on the bracket 3 and arranged oppositely.

The first serial group 11 may be configured to be connected in series with one cell group 71, and the second serial group 12 may be configured to be connected in series with another cell group 71. The first serial group 11 and the second serial group 12 may each include a first serial row 101 and a second serial row 102 arranged oppositely. The first serial row 101 and the second serial row 102 may be provided in the same number, the first serial row 101 and the second serial row 102 may be both configured to connect positive and negative electrodes of adjacent cells, and the first serial row 101 and the second serial row 102 arranged oppositely may be configured to connect the positive and negative electrodes of the same cell. The first connection member 21 may be disposed between the first serial group 11 and the second serial group 12 and configured to connect two first serial rows 101 or two second serial rows 102 of the first serial group 11 and the second serial group 12 in series, and further connects cell groups 71 corresponding to the first serial group 11 and the second serial group 12 in series, thereby realizing integration of the cell group 71 corresponding to the first serial group 11 with the cell group 71 corresponding to the second serial group 12.

The bracket 3 may be provided with a plurality of explosion-proof holes 33 for exposing cell explosion-proof valves, where the plurality of explosion-proof holes 33 are respectively provided between the first serial row 101 and the second serial row 102 to ensure smooth operation of the cell explosion-proof valves.

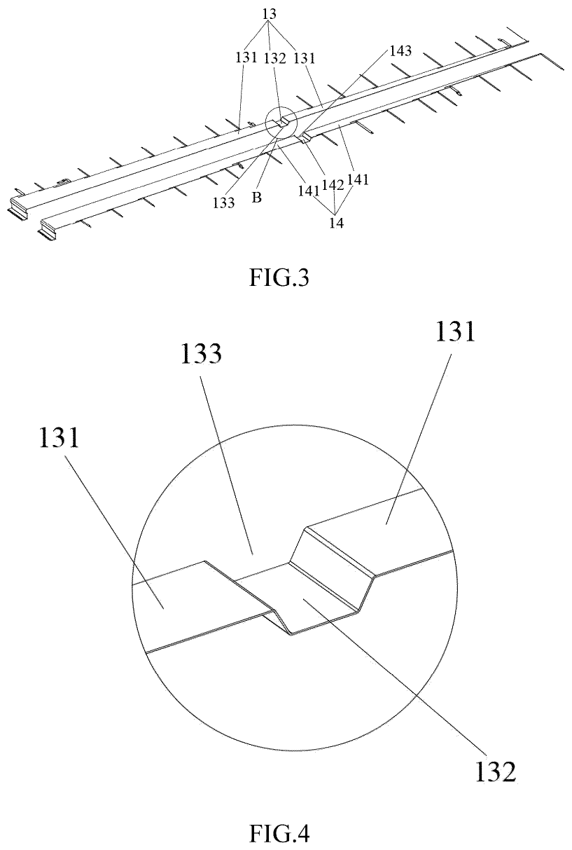

Referring to FIGS. 1 and 3, the first collection line 13 and the second collection line 14 may be positioned between the first serial row 101 and the second serial row 102, the first collection line 13 may be electrically connected to the two first serial rows 101 of the first serial group 11 and the second serial group 12, and the second collection line 14 may be electrically connected to the two second serial rows 102 of the first serial group 11 and the second serial group 12. The first collection line 13 and the second collection line 14 may be configured to collect voltage and temperature signals and the like of the cell groups 71.

The serial assembly 110 may further include two connection circuit boards 4 respectively connected to the first collection line 13 and the second collection line 14, where the two connection circuit boards 4 may be provided at one ends of the first collection line 13 and the second collection line 14, respectively, so as to facilitate connection with connectors of the CSC assembly.

Referring to FIGS. 3 and 4, the first collection line 13 may include two first connection portions 131 and a first buffer portion 132 connected between the two first connection portions 131. The two first connection portions 131 may be connected to the two first serial rows 101 of the first serial group 11 and the second serial group 12, respectively, and the first buffer portion 132 may be provided with a first groove 133 facing the bracket 3. In an extension direction of the first collection line 13, a distance between the first groove 133 and the first serial row 101 of the first serial group 11 may be equal to a distance between the first groove 133 and the first serial row 101 of the second serial group 12.

The second collection line 14 may include two second connection portions 141 and a second buffer portion 142 connected between the two second connection portions 141, the two second connection portions 141 may be connected to the two second serial rows 102 of the first serial group 11 and the second serial group 12, respectively, and the second buffer portion 142 may be provided with a second groove 143 facing the bracket 3. In an extension direction of the second collection line 14, a distance between the second groove 143 and the second serial row 102 of the first serial group 11 may be equal to a distance between the second groove 143 and the second serial row 102 of the second serial group 12. As such, the first groove 133 and the second groove 143 both may be positioned between the first serial row 101 and the second serial row 102. When a cell of a battery module emits heat and is expanded, a tension force to which the two first connection portions 131 and the two second connection portions 141 are subjected from the cell is made as equal as possible, thereby enabling the first buffer portion 132 and the second buffer portion 142 to be stretched to a large extent to better adapt to expansion of the cell.

A virtual connection line between the center of the first groove 133 and the center of the second groove 143 may be perpendicular to the extension direction of the first collection line 13, so that extension directions of the first buffer portion 132 and the second buffer portion 142 are the same as each other.

A cell expansion amount may be calculated by model simulation. For example, when the cell expansion amount is 1.5 mm, the lengths of the first buffer portion 132 and the second buffer portion 142 are twice the cell expansion amount, that is, 3.0 mm.

Referring to FIGS. 1 and 5, the first connection member 21 may be provided with a first protrusion 211 away from the bracket 3 and two first recesses 212 on both sides of the first protrusion 211, where the two first recesses 212 are recessed toward the bracket 3.

As such, the first connection member 21 may have a W-shaped-like structure. When the cell emits heat and is expanded, the first connection member 21 can be expanded to accommodate the cell expansion amount. Additionally, compared with a solution in which the first connection member 21 is provided with one first recess 212, the first protrusion 211 may be provided between the two first recesses 212, which can improve a structural strength of the first connection member 21, and prevent the first connection member 21 from being broken away as much as possible without plastic deformation.

The first protrusion 211 may extend in an extension direction perpendicular to the first collection line 13.

Widths and depths of the first protrusion 211 and the first recess 212 may be determined according to actual cell expansion amount and a tensile force test. In the present embodiment, the size of the first connection member 21 is 114.4 mm*61 mm*1.2 mm, and the depth of the first recess 212 is equal to the height of the first protrusion 211, which both are 3.5 mm. In the present embodiment, the serial assembly 110 may be made of aluminum, and the bracket 3 may be made of plastic.

Referring to FIGS. 1, 10, and 11, an embodiment of the present disclosure may further provide a battery module, including: the battery module collection mechanism 1 described in any one of the above embodiments, a cell grouping assembly 7, and an integrated connection assembly.

The battery module collection mechanism 1 may be provided in two, where the two battery module collection mechanisms 1 correspond to two cell grouping assemblies 7, respectively. The cell grouping assembly 7 may include four cell groups 71, and the collection group 100 may be provided in two, where one of the two collection groups 100 corresponds to two of the four cell groups 71. The two cell groups 71 may be electrically connected to the first serial group 11 and the second serial group 12, respectively, and the integrated connection assembly may include a first integrated member 22 and a second integrated member 23.

When the first connection member 21 may be connected to the two first serial rows 101 of the first serial group 11 and the second serial group 12, the first integrated member 22 may be connected to the two second serial rows 102 of the two collection groups 100, the two second serial rows 102 of the two first serial groups 11 of the two battery module collection mechanisms 1 may be connected to each other through the second integrated member 23, and the second integrated member 23 may be provided on one side of the first serial row 101 away from the first integrated member 22.

Alternatively, when the first connection member 21 may be connected to the two second serial rows 102 of the first serial group 11 and the second serial group 12, the first integrated member 22 may be connected to the two first serial rows 101 of the two collection groups 100, the two first serial rows 102 of the two first serial groups 11 of the two battery module collection mechanisms 1 may be connected to each other through the second integrated member 23, and the second integrated member 23 may be provided on one side of the first serial row 101 away from the first integrated member 22. The second integrated member 23 may be sleeved with an insulating sleeve for insulating the second integrated member 23 from a case beam of the battery module, which can protect the battery from being short-circuited when a safe distance between the second integrated member 23 and the case beam of the battery module is smaller.

In the present embodiment, the first connection member 21 may be connected to the two second serial rows 102 of the first serial group 11 and the second serial group 12. In this case, a flow path of a current of the battery module may be as follows: in one of the collection groups 100, the current flows through the cell group 71 corresponding to the first serial group 11 via the first serial group 11 and the second serial group 12 having the first serial rows 101 connecting adjacent cells in series, and the current flows into a second serial row 102 of the second serial group 12 through the first connection member 21 and flows through the cell group 71 corresponding to the second serial group 12; then the current flows into a first serial row 101 of a first serial group 11 in another of the collection groups 100 via the first integrated member 22, and flows through the cell group 71 corresponding to the first serial group 11, the current flows into a second serial row 102 of a second serial group 12 through the first connection member 21 and flows through the cell group 71 corresponding to the second serial group 12; and finally, the current flows into a first serial row 101 of a first serial group 11 of another battery module collection mechanism 1 through the second integrated member 23.

Virtual extension lines of two first protrusions of two first connectors 21 of the two collection groups 100 may coincide with each other, so that the two first connectors 21 of the battery module collection mechanism 1 may be uniformly stressed, thereby facilitating better adaptation to the expansion of the cell.

In other embodiments, two first connectors 21 of two collection groups 100 may connect two first serial rows 101 or two second serial rows 102, respectively.

Integration of the four cell groups 71 may be achieved by the first connection member 21 and the first integrated member 22, and the four battery modules may be integrated into one larger battery module, thereby increasing the energy density. By extending the collection line on the original basis, the number of CSC assemblies may be reduced, thereby reducing the intermediate transfer harness.

In other embodiments, the battery grouping assembly 7 may also be provided in three, four or even more, the battery module collection mechanism 1 may be provided in a number corresponding to the number of the battery grouping assemblies 7, and the collection group 100 may also be provided in three, four or even more. Cell grouping groups 7 corresponding to different battery module collection mechanisms 1 may be electrically connected through the second integrated member 23, and the different collection groups 100 may be electrically connected through the first integrated member 22.

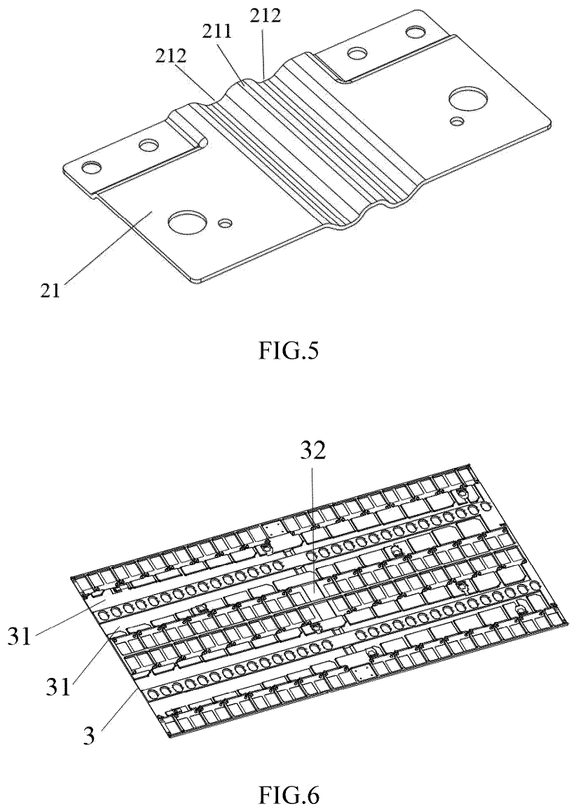

Referring to FIG. 6, the bracket 3 may be provided with four collection line installing grooves 31 for installing collection groups 100 and two connection member installing grooves 32 for installing the first connection member 21 and the second connection member, and the collection line installing grooves 31 and the connection member installing grooves 32 may be designed according to shapes of the collection groups and the connection member.

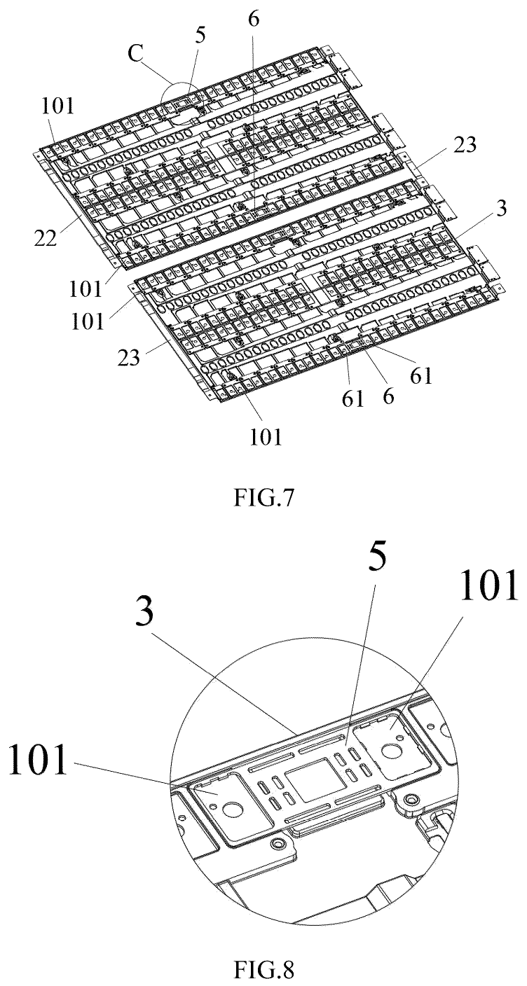

Referring to FIG. 7, the battery module may further include a positioning member including a first positioning member 5 and a second positioning member 6 arranged oppositely, where the first positioning member 5 and the second positioning member 6 are heat-riveted to the bracket 3 and each disposed on one side of the bracket 3 toward the cell group 71. The first positioning member 5 may be positioned between the two first serial rows 101 of the first serial group 11 and the second serial group 12 of one collection group 100, and the second positioning member 6 may be positioned between the two first serial rows 101 of the first serial group 11 and the second serial group 12 of another collection group 100.

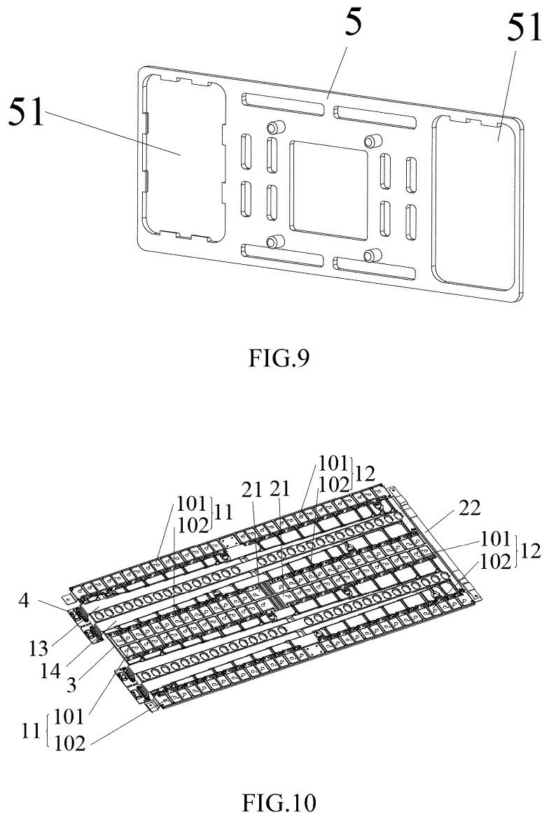

Referring to FIGS. 7, 8 and 9, the first positioning member 5 may be provided with two first positioning grooves 51, that is, positioning grooves of the positioning members, where the two first positioning grooves 51 respectively expose a portion of the two first serial rows 101. The first positioning grooves 51 may be configured to embed poles of the cell into the first positioning grooves 51, and serve as positioning functions when the cell is welded to the first serial row 101.

The second positioning member 6 may be provided with two second positioning grooves 61, that is, positioning grooves of the positioning members, where the two second positioning grooves 61 respectively expose a portion of the two first serial rows 101 of the first serial group 11 and the second serial group 12 of another collection group 100. The second positioning grooves 61 may be configured to embed poles of the cell into the second positioning grooves 61, and serve as positioning functions when the cell is welded to the two first serial rows 101 of the first serial group 11 and the second serial group 12 of another collection group 100.

What is claimed is:

1. A battery module collection mechanism, comprising:
a bracket; and
a collection group comprising a serial assembly;
wherein the serial assembly comprises a first serial group, a second serial group, and a first connection member all disposed on the bracket, the first serial group and the second serial group each comprises a first serial row and a second serial row arranged oppositely, and the first serial group and the second serial group each is connected in series with a cell group, and two first serial rows or two second serial rows of both the first serial group and the second serial group are connected to each other by the first connection member.

2. The battery module collection mechanism of claim 1, wherein the first connection member is provided with a first protrusion away from the bracket.

3. The battery module collection mechanism of claim 2, wherein the collection group is provided in two, and virtual extension lines of two first protrusions of the two collection groups coincide with each other.

4. The battery module collection mechanism of claim 2, wherein the first connection member is provided with two first recesses on both sides of the first protrusion.

5. The battery module collection mechanism of claim 2, wherein the collection group further comprises a collection assembly, the collection assembly comprises a first collection line and a second collection line each installed on the bracket and arranged oppositely; and the first collection line is electrically connected to two first serial rows of both the first serial group and the second serial group, and the second collection line is electrically connected to two second serial rows of both the first serial group and the second serial group.

6. The battery module collection mechanism of claim 5, wherein the first collection line comprises two first connection portions and a first buffer portion connected between the two first connection portions, the two first connection portions are connected to the two first serial rows of both the first serial group and the second serial group, respectively, and the first buffer portion is provided with a first groove toward the bracket; the second collection line comprises two second connection portions and a second buffer portion connected between the two second connection portions, the two second connection portions are connected to the two second serial rows of both the first serial group and the second serial group, respectively, and the second buffer portion is provided with a second groove toward the bracket; and a virtual connection line between a center of the second groove and a center of the first groove is perpendicular to an extension direction of the first collection line.

7. The battery module collection mechanism of claim 6, wherein extension directions of two first collection lines of the two collection groups are parallel to each other.

8. A battery module, comprising one or more battery grouping assemblies and the battery module collection mechanism of claim 1 provided in a number corresponding to a number of the battery grouping assemblies, wherein each of the battery grouping assemblies comprises four cell groups, the battery module collection mechanism comprises two collection groups, and each of the collection groups corresponds to two of the cell groups.

9. The battery module of claim 8, further comprising an integrated connection assembly comprising a first integrated member, wherein two first serial rows of two serial assemblies are interconnected with each other by the first integrated member, the first integrated member is configured to connect the two second serial rows of the two collection groups when the first connection member is configured to connect the two first serial row of both the first serial group and the second serial group, and the first integrated member is configured to connect the two first serial rows of the two collection groups when the first connection member is configured to connect the two second serial row of both the first serial group and the second serial group.

10. The battery module of claim 9, wherein the cell grouping assemblies are provided in two, the battery module collection mechanism is provided in two corresponding to the two cell grouping assemblies, the integrated connection assembly comprises a second integrated member disposed on a side of the first serial row away from the first integrated member, the two second serial rows of the two first serial groups of the two battery module collection mechanisms are interconnected with each other by the second integrated member when the first connection member is configured to connect the two first serial rows of both the first serial group and the second serial group, and the two first serial rows of the two first serial groups of the two battery module collection mechanisms are interconnected with each other by the second integrated member when the first connection member is configured to connect the two second serial rows of both the first serial group and the second serial group.

11. The battery module of claim 9, further comprising a positioning member connected to a side of the bracket toward the battery grouping assemblies, wherein the positioning member is positioned between the two first serial rows or the second serial rows of both the first serial group and the second serial group, and the positioning member is provided with a positioning groove for embedding a pole of a cell into the positioning groove.

12. A battery module, comprising one or more battery grouping assemblies and the battery module collection mechanism of claim 2 provided in a number corresponding to a number of the battery grouping assemblies, wherein each of the battery grouping assemblies comprises four cell groups, the battery module collection mechanism comprises two collection groups, and each of the collection groups corresponds to two of the cell groups.

13. The battery module of claim 12, further comprising an integrated connection assembly comprising a first integrated member, wherein two first serial rows of two serial assemblies are interconnected with each other by the first integrated member, the first integrated member is configured to connect the two second serial rows of the two collection groups when the first connection member is configured to connect the two first serial row of both the first serial group and the second serial group, and the first integrated member is configured to connect the two first serial rows of the two collection groups when the first connection member is configured to connect the two second serial row of both the first serial group and the second serial group.

14. The battery module of claim 13, wherein the cell grouping assemblies are provided in two, the battery module collection mechanism is provided in two corresponding to the two cell grouping assemblies, the integrated connection assembly comprises a second integrated member disposed on a side of the first serial row away from the first integrated member, the two second serial rows of the two first serial groups of the two battery module collection mechanisms are interconnected with each other by the second integrated member when the first connection member is configured to connect the two first serial rows of both the first serial group and the second serial group, and the two first serial rows of the two first serial groups of the two battery module collection mechanisms are interconnected with each other by the second integrated member when the first connection member is configured to connect the two second serial rows of both the first serial group and the second serial group.

15. The battery module of claim 13, further comprising a positioning member connected to a side of the bracket toward the battery grouping assemblies, wherein the positioning member is positioned between the two first serial rows or the second serial rows of both the first serial group and the second serial group, and the positioning member is provided with a positioning groove for embedding a pole of a cell into the positioning groove.

16. A battery module, comprising one or more battery grouping assemblies and the battery module collection mechanism of claim 3 provided in a number corresponding to a number of the battery grouping assemblies, wherein each of the battery grouping assemblies comprises four cell groups, the battery module collection mechanism comprises two collection groups, and each of the collection groups corresponds to two of the cell groups.

17. A battery module, comprising one or more battery grouping assemblies and the battery module collection mechanism of claim 4 provided in a number corresponding to a number of the battery grouping assemblies, wherein each of the battery grouping assemblies comprises four cell groups, the battery module collection mechanism comprises two collection groups, and each of the collection groups corresponds to two of the cell groups.

18. A battery module, comprising one or more battery grouping assemblies and the battery module collection mechanism of claim 5 provided in a number corresponding to a number of the battery grouping assemblies, wherein each of the battery grouping assemblies comprises four cell groups, the battery module collection mechanism comprises two collection groups, and each of the collection groups corresponds to two of the cell groups.

19. A battery module, comprising one or more battery grouping assemblies and the battery module collection mechanism of claim 6 provided in a number corresponding to a number of the battery grouping assemblies, wherein each of the battery grouping assemblies comprises four cell groups, the battery module collection mechanism comprises two collection groups, and each of the collection groups corresponds to two of the cell groups.

20. A battery module, comprising one or more battery grouping assemblies and the battery module collection mechanism of claim 7 provided in a number corresponding to a number of the battery grouping assemblies, wherein each of the battery grouping assemblies comprises four cell groups, the battery module collection mechanism comprises two collection groups, and each of the collection groups corresponds to two of the cell groups.
